(19) United States
(12) Patent Application Publication
(10) Pub. No.: US 2010/0181639 A1
(43) Pub. Date: Jul. 22, 2010

(54) SEMICONDUCTOR DEVICES AND FABRICATION METHODS THEREOF

(75) Inventors: Wei-Tsung Huang, Taichung County (TW); Pi-Kuang Chuang, Taichung City (TW); Shih-Ming Chen, Hsinchu City (TW); Hsiao-Ying Yang, Hsinchu City (TW)

Correspondence Address: QUINTERO LAW OFFICE, PC, 615 Hampton Dr, Suite A202, Venice, CA, 90291, US

(73) Assignee: VANGUARD INTERNATIONAL SEMICONDUCTOR CORPORATION, Hsinchu (TW)

(21) Appl. No.: 12/356,036

(22) Filed: Jan. 19, 2009

(51) Int. Cl. H01L 23/58; H01L 21/76

(52) U.S. Cl. 257/506; 438/425; 257/E23.002; 257/E21.532

(57) ABSTRACT

A semiconductor device is provided. The semiconductor device comprises an epitaxial layer disposed on a semiconductor substrate, a plurality of electronic devices disposed on the epitaxial layer and a trench isolation structure disposed between the electric devices. The trench isolation structure comprises a trench in the epitaxial layer and the semiconductor substrate, an oxide liner on the sidewall and bottom of the trench, and a doped polysilicon layer filled in the trench. Moreover, a zero bias voltage can be applied to the doped polysilicon layer. The trench isolation structure can be used for isolating electronic devices having different operation voltages or high-voltage devices.

### BACKGROUND OF THE INVENTION

1. Field of the Invention

The invention relates to semiconductor devices and more particularly to semiconductor devices having trench isolation structures and fabrication methods thereof.

2. Description of the Related Art

System-on-a-chip integrated circuits comprising controllers, memories, low-voltage operating circuits and high-voltage power devices have become more popular recently, driven by advanced developments in semiconductor integrated circuit manufacturing techniques. Since electronic devices with different operating voltages are provided on the system-on-a-chip, for example, a high-voltage transistor and a low-voltage complementary metal-oxide-semiconductor (CMOS), an isolation structure is required to isolate the electronic devices with different operating voltages.

Referring to FIG. 1, a cross section of a conventional isolation structure for electronic devices is shown. An epitaxial layer 12 is disposed on a semiconductor substrate 10. Two electronic devices 14 and 16 are disposed in the epitaxial layer 12. An isolation structure 18 is disposed between the electronic devices 14 and 16, and is formed by junction isolation. The junction isolation structure 18 is formed by driving a dopant into the epitaxial layer 12 by an ion implantation method. Because the junction isolation structure 18 requires a relatively larger area on the semiconductor substrate 10 for chip layout and the actual isolation area required thereof is difficult to accurately estimate, the size of the chip containing the junction isolation structure 18 is relatively large.

Moreover, another conventional isolation structure for electronic devices is a deep trench isolation structure, which is formed from forming a deep trench between two electronic devices and fills the deep trench with an oxide or an undoped polysilicon. Although the deep trench isolation structure requires a relatively smaller area on the semiconductor substrate for chip layout and the actual isolation area required thereof is more easy to accurately estimate, the isolation effect is affected by an aspect ratio of the deep trench and a dielectric constant of the filling material in the deep trench. Therefore, the conventional deep trench isolation structure can not be used for electronic devices with various operating voltages and the application thereof is limited.

Therefore, an isolation structure for semiconductor devices capable of overcoming the above problems is desired.

### BRIEF SUMMARY OF THE INVENTION

A semiconductor device and a fabrication method thereof are provided. An exemplary embodiment of the semiconductor device comprises a semiconductor substrate, wherein an epitaxial layer is disposed on the semiconductor substrate. A plurality of electronic devices is disposed on the epitaxial layer and a trench isolation structure is disposed between the electronic devices. The trench isolation structure comprises a trench disposed in the epitaxial layer and the semiconductor substrate, having a sidewall and a bottom. An oxide liner is disposed in the trench, covering the sidewall and the bottom of the trench and a doped polysilicon layer is filled in the trench.

An exemplary embodiment of the method for fabricating the semiconductor devise comprises providing a semiconductor substrate. An epitaxial layer is formed on the semiconductor substrate and a plurality of electronic devices is formed on the epitaxial layer. An interlayer dielectric layer is formed on the epitaxial layer, covering the electronic devices and a trench isolation structure is formed between the electronic devices. The step of forming the trench isolation structure comprises forming a trench in the interlayer dielectric layer, the epitaxial layer and the semiconductor substrate by a photolithography and an etching process. An oxide liner is formed to cover a sidewall and a bottom of the trench and a surface of the interlayer dielectric layer. A doped polysilicon layer is formed on the oxide liner and fills the trench. Then, a portion of the oxide liner and a portion of the doped polysilicon layer are removed to expose the surface of the interlayer dielectric layer by a chemical mechanical polishing process.

A detailed description is given in the following embodiments with reference to the accompanying drawings.

### BRIEF DESCRIPTION OF DRAWINGS

The invention can be more fully understood by reading the subsequent detailed description and examples with references made to the accompanying drawings, wherein:

FIG. 1 is a schematic cross section of a semiconductor device having a conventional isolation structure;

FIG. 2 is a schematic cross section of a semiconductor device having a trench isolation structure according to an exemplary embodiment of the invention; and

FIGS. 3A to 3F are cross sections of a method for fabricating a trench isolation structure according to an exemplary embodiment of the invention.

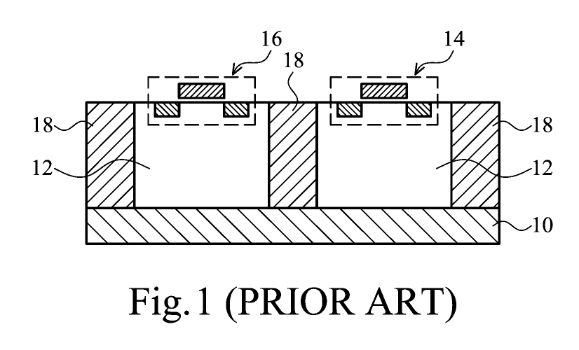

### DETAILED DESCRIPTION OF INVENTION

The following description is of the best-contemplated mode of carrying out the invention. This description is made for the purpose of illustrating the general principles of the invention and should not be taken in a limiting sense. The scope of the invention is best determined by reference to the appended claims.

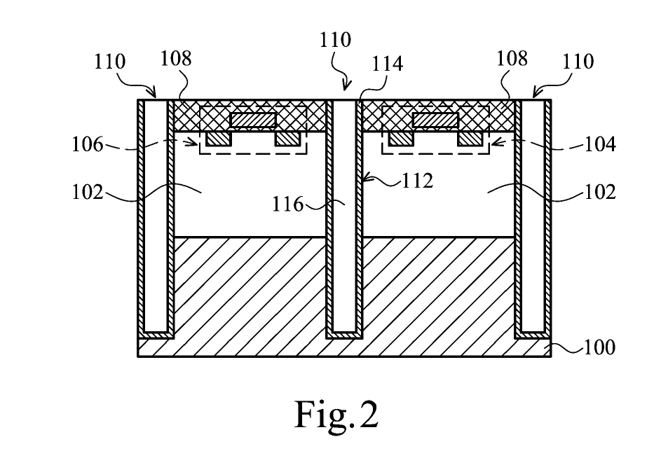

Referring to FIG. 2, a schematic cross section of a semiconductor device according to an exemplary embodiment of the invention is shown. In order to simplify the diagram, only two electronic devices are shown in FIG. 2. One skilled in the art should appreciate that more than two electronic devices can be disposed in the semiconductor device. To begin, an epitaxial layer 102 is disposed on a semiconductor substrate 100. Two electronic devices 104 and 106 are formed on the epitaxial layer 102. The electronic devices 104 and 106 may have different operating voltages or have the same high operating voltage. The electronic devices 104 and 106 may be a driver integrated circuits (ICs) device, a logic device, a mix mode device, a bipolar-complementary metal oxide semiconductor (CMOS)-diffused metal oxide semiconductor (DMOS) device (BCD device), a high-voltage device, a smart power integrated circuits (ICs) device, or the combinations thereof. In order to simplify the diagram, the detailed structures of the electronic devices 104 and 106 well known in the art are omitted.

An interlayer dielectric layer (ILD) 108 is formed on the epitaxial layer 102 to cover the electronic devices 104 and 106. The interlayer dielectric layer 108 can protect the electronic devices and be used as an insulating layer. A trench isolation structure 110 is disposed between the electronic devices 104 and 106. The trench isolation structure 110 contains a trench 112, an oxide liner 114 and a doped polysilicon layer 116. The oxide liner 114 is conformally formed on the sidewall and the bottom of the trench 112. The doped polysilicon layer 116 is disposed on the oxide liner 114 to fill the trench 112. The surfaces of the oxide liner 114, the doped polysilicon layer 116 and the interlayer dielectric layer 108 are at the same level.

In one embodiment, the oxide liner 114 can consist of a plurality of oxide layers, for example a plurality of tetraethoxysilane (TEOS) oxide layers. The thickness of each oxide layer can be different and about 1000 Å to 6000 Å, which is determined by the aspect ratio of the trench and the difference in operating voltage between the electronic devices. In one embodiment, the doped polysilicon layer 116 may be a heavily doped N-type (N⁺) or a heavily doped P-type (P⁺) polysilicon, wherein the P⁺ polysilicon is preferred. In one embodiment, the trench 112 can be a deep trench having a width of about 1 m to about 10 μm and a depth of about 5 μm to about 50 μm. The deep trench has an aspect ratio of about 5:1 to about 15:1. The width of the trench 112 is determined by the isolation effect requirement for electronic devices. The depth of the trench 112 is determined by the difference in operating voltage between the electronic devices.

According to one exemplary embodiment of the invention, the doped polysilicon layer 116 filled in the trench 112 can be used as an electrode. While a bias voltage is applied to the doped polysilicon layer 116, the equipotential lines of the semiconductor device can be forced to go around the trench 112. Therefore, the interference between the electronic devices having different operating voltages is avoided and the isolation effect for the high-voltage devices is enhanced to avoid current leakage. In one embodiment, a zero bias voltage can be applied to the doped polysilicon layer 116.

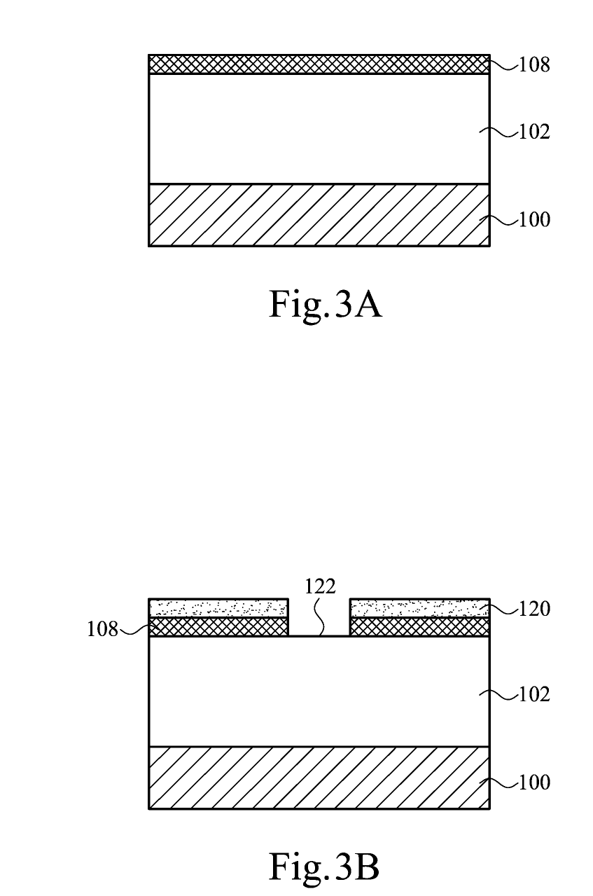

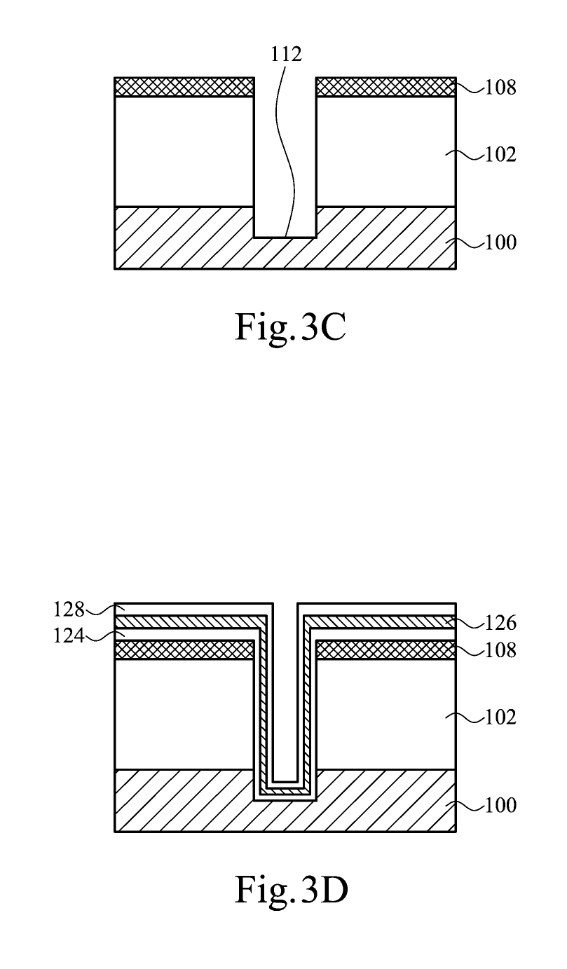

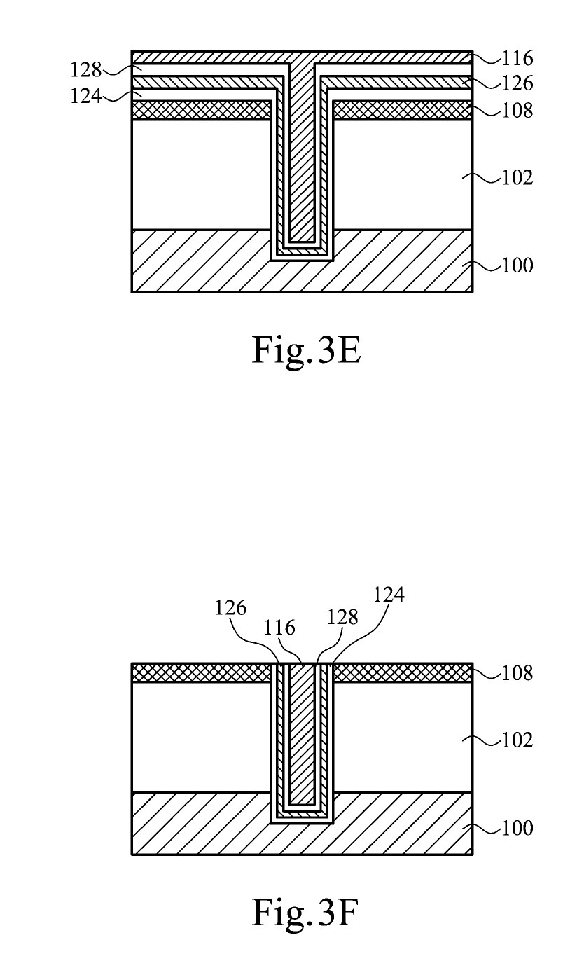

Referring to FIGS. 3A to 3F, cross sections of a method for fabricating a trench isolation structure according to an exemplary embodiment of the invention are shown. As shown in FIG. 3A, the epitaxial layer 102 is formed on the semiconductor substrate 100. The plurality of electronic devices 104 and 106 as shown in FIG. 2 are formed on the epitaxial layer 102. In order to simplify the diagram, the electronic devices are not shown in FIGS. 3A to 3F. Then, the interlayer dielectric layer 108 is formed on the epitaxial layer 102 to cover the entire surface of the semiconductor device.

Referring to FIG. 3B, a patterned photoresist layer 120 with a pattern corresponding to the trench is formed on the interlayer dielectric layer 108 by a photolithography process. The patterned photoresist layer 120 is used to define the width of the trench. Then, the patterned photoresist layer 120 is used as a mask to etch an exposed area of the interlayer dielectric layer 108 to form an opening 122.

Referring to FIG. 3C, the interlayer dielectric layer 108 with the opening 122 is used as a mask to etch the epitaxial layer 102 and the semiconductor substrate 100 under the opening 122 to form the deep trench 112. For example, the deep trench 112 has a width of about 2 μm and a depth of about 20 μm. Next, referring to FIG. 3D, a first oxide liner 124 is conformally formed on the sidewall and the bottom of the trench 112 and the surface of the interlayer dielectric layer 108 by a low pressure chemical vapor deposition (LPCVD) process. Then, a second and a third oxide liner 126 and 128 are conformally formed on the first oxide liner 124 in sequence by a low pressure chemical vapor deposition (LPCVD) process. The first, the second and the third oxide liners can be tetraethoxysilane (TEOS) oxide layers. The thicknesses of the first, the second and the third oxide liners may be 2000 Å, 5000 Å and 5000 Å, respectively. A better step coverage on the sidewall and the bottom of the trench can be achieved by repeatedly using the low pressure chemical vapor deposition process to form several layers of the oxide liners by several times. Therefore, a uniform coverage of the oxide liner thin film on the sidewall and the bottom of the trench having a high aspect ratio can be achieved.

Referring to FIG. 3E, the doped polysilicon layer 116 is formed on the oxide liner 128 to cover the entire surface of the semiconductor device and fill the deep trench 112. In one embodiment, silane (SiH₄) can be used as a reactive gas and helium (He) can be used as a carrier gas. Boron ions (B⁺) can be added during the deposition process, for example, diborane (B₂H₆) is added into the above mixture of gases to form a heavily doped P-type (P⁺) polysilicon layer.

Next, referring to FIG. 3F, a portion of the doped polysilicon layer 116 and a portion of the oxide liners 124, 126 and 128 are removed by a chemical mechanical polishing (CMP) process until a surface of the interlayer dielectric layer 108 is exposed. Thus, the surfaces of the oxide liners 124, 126 and 128, the doped polysilicon layer 116 and the interlayer dielectric layer 108 are at the same level to complete one exemplary embodiment of the trench isolation structure of the invention.

According to the aforementioned embodiments, the doped polysilicon layer filled into the trench isolation structure can be used as an electrode. Therefore, if a bias voltage is applied to the doped polysilicon layer, it can force the equipotential lines to go around the trench isolation structure. Accordingly, the trench isolation structure of the invention can have better isolation ability for electronic devices with different operating voltages. Meanwhile, the trench isolation structure of the invention has better isolation ability for high voltage devices. Compared to the conventional isolation structure between electronic devices, the size of the trench isolation structure of the invention can be reduced. Moreover, the trench isolation structure of the invention can be applied to electronic devices with different operating voltages. The isolation effect of the trench isolation structure of the invention will not be affected by the dielectric constant of the filling materials in the trench. Therefore, the application of the trench isolation structure of the invention is expanded, especially for various electronic devices with different operating voltages and high voltage devices.

While the invention has been described by way of example and in terms of the preferred embodiments, it is to be understood that the invention is not limited to the disclosed embodiments. To the contrary, it is intended to cover various modifications and similar arrangements (as would be apparent to those skilled in the art). Therefore, the scope of the appended claims should be accorded the broadest interpretation so as to encompass all such modifications and similar arrangements.

What is claimed is:

1. A semiconductor device, comprising:
a semiconductor substrate;
an epitaxial layer disposed on the semiconductor substrate;
a plurality of electronic devices disposed on the epitaxial layer; and
a trench isolation structure disposed between the electronic devices,
wherein the trench isolation structure comprises;
a trench disposed in the epitaxial layer and the semiconductor substrate, having a sidewall and a bottom;
an oxide liner disposed in the trench, covering the sidewall and the bottom; and
a doped polysilicon layer filled in the trench.

2. The semiconductor device as claimed in claim 1, further comprising a zero bias voltage applied to the doped polysilicon layer.

3. The semiconductor device as claimed in claim 1, wherein the trench comprises a deep trench.

4. The semiconductor device as claimed in claim 4, wherein the deep trench has an aspect ratio of 5:1 to 15:1.

5. The semiconductor device as claimed in claim 1, wherein the oxide liner comprises a plurality of tetraethoxysilane (TEOS) oxide layers.

6. The semiconductor device as claimed in claim 1, wherein the doped polysilicon layer comprises a heavily doped N-type or a heavily doped P-type polysilicon.

7. The semiconductor device as claimed in claim 1, wherein the electronic devices comprise a high-voltage device, a mix mode device, a driver integrated circuits device, a logic device or the combinations thereof.

8. The semiconductor device as claimed in claim 1, wherein the electronic devices have different operating voltages.

9. The semiconductor device as claimed in claim 1, further comprising an interlayer dielectric layer disposed on the epitaxial layer, covering the electronic devices.

10. The semiconductor device as claimed in claim 9, wherein a surface of the trench isolation structure is at the same level with a surface of the interlayer dielectric layer.

11. A method for fabricating a semiconductor device, comprising:
providing a semiconductor substrate;
forming an epitaxial layer on the semiconductor substrate;
forming a plurality of electronic devices on the epitaxial layer;
forming an interlayer dielectric layer on the epitaxial layer, covering the electronic devices; and
forming a trench isolation structure between the electronic devices,
wherein the step of forming the trench isolation structure comprises:
forming a trench in the interlayer dielectric layer, the epitaxial layer and the semiconductor substrate by a photolithography and an etching process;
forming an oxide liner, covering a sidewall and a bottom of the trench and a surface of the interlayer dielectric layer;
forming a doped polysilicon layer on the oxide liner and filled into the trench; and
removing a portion of the oxide liner and a portion of the doped polysilicon layer to expose the surface of the interlayer dielectric layer by a chemical mechanical polishing process.

12. The method as claimed in claim 11, further comprising applying a zero bias voltage to the doped polysilicon layer.

13. The method as claimed in claim 11, wherein the trench comprises a deep trench.

14. The method as claimed in claim 13, wherein the deep trench has an aspect ratio of 5:1 to 15:1.

15. The method as claimed in claim 11, wherein the step of forming the oxide liner comprises a low pressure chemical vapor deposition process.

16. The method as claimed in claim 11, wherein the oxide liner comprises a plurality of tetraethoxysilane (TEOS) oxide layers.

17. The method as claimed in claim 11, wherein the doped polysilicon layer comprises a heavily doped N-type or a heavily doped P-type polysilicon.

18. The method as claimed in claim 11, wherein the step of forming the doped polysilicon layer comprises a chemical vapor deposition process.

19. The method as claimed in claim 11, wherein the electronic devices comprise a high-voltage device, a mix mode device, a driver integrated circuit device, a logic device or the combinations thereof.

20. The method as claimed in claim 11, wherein the electronic devices have different operating voltages.
